(19) United States
(12) Patent Application Publication
(10) Pub. No.: US 2023/0028395 A1
(43) Pub. Date: Jan. 26, 2023

(54) POLYMERS, COMPOSITIONS AND METHOD FOR MANUFACTURING AN ARTICLE BY 3D PRINTING

(71) Applicant: SOLVAY SPECIALTY POLYMERS USA, LLC, Alpharetta, GA (US)

(72) Inventors: Joel Pollino, Johns Creek, GA (US); Kermit S. Kwan, Cumming, GA (US); Stéphane Jeol, Saint-Genis-Laval (FR); Eduardo Soriano, Atlanta, GA (US)

(73) Assignee: SOLVAY SPECIALTY POLYMERS USA, LLC, Alpharetta, GA (US)

(21) Appl. No.: 17/778,792

(22) PCT Filed: Nov. 19, 2020
(86) PCT No.: PCT/EP2020/082642

§ 371 Date: May 20, 2022

Related U.S. Application Data
(60) Provisional application No. 62/938,537, filed on Nov. 21, 2019.

(30) Foreign Application Priority Data
Mar. 24, 2020 (EP) 20165237.7

(51) Int. Cl. C08G 65/40; C08G 75/23; B33Y 70/00; B33Y 10/00; B29C 64/129

(52) U.S. Cl. CPC C08G 65/40; C08G 75/23; B33Y 70/00; B33Y 10/00; B29C 64/129; B29K 2071/00

(57) ABSTRACT

The present invention relates to poly(aryl ether) polymers which can for example be used in lithographic processes for the photofabrication of three-dimensional (3D) articles. The invention further relates to compositions including these poly(aryl ether) polymers. Still further, the invention relates to lithographic methods to form 3D articles or objects that incorporate the aforementioned polymer compositions.

### RELATED APPLICATIONS

This application claims priority to U.S. provisional application U.S. 62/938,537 filed on Nov. 21, 2019 and to European patent application 20165237.7 filed on Mar. 24, 2020, the whole content of these applications being incorporated herein by reference for all purposes.

### TECHNICAL FIELD

The present invention relates to poly(aryl ether) polymers which can for example be used in lithographic processes for the photofabrication of three-dimensional (3D) articles. The invention further relates to formulations including these poly(aryl ether) polymers. Still further, the invention relates to lithographic methods to form three-dimensional (3D) objects that incorporate the aforementioned polymer formulations.

### BACKGROUND

Polymer compositions are commonly used to manufacture articles for the automotive and aerospace industries, for example as engine parts, as well as in the healthcare industry, for example as implantable devices and dental prostheses. These articles have to present good mechanical properties after fabrication, but they also have to retain a sufficient percentage of these properties over time, notably at their temperature of use (sometimes higher than 150° C.).

Lithographic process for the photofabrication of 3D articles from polymeric materials have found recent popularity due to their relative speed and simplicity. In general, lithographic processes involve the use of light, for example UV irradiation, to locally cure a polymerizable composition at specific locations. The localized curing allows for the fabrication of 3-dimensional articles.

Lithographic processes generally use polymerizable compositions that are liquid in order to obtain parts with a good resolution. Polymerizable compositions that are liquid at room temperature are easier to use in a printing process, but they generally lead to articles having moderate mechanical properties and thermal stability.

Certain polymers present a better mechanical property profile, but they need to be above their melting temperature to be used in lithographic processes. Additionally, these polymers not only need to be reactive in the printing process, when irradiating the layer of polymer, but they also need to be sufficiently thermally stable at temperatures required to melt the polymers.

WO18035368A1 relates to a polymer resin for vat photopolymerization. The polymer resin can include a polyamic diacrylate ester or salt thereof, the polyamic diacrylate ester or salt comprising a plurality of photocrosslinkable groups pendantly attached thereto; a photoinitiator suitable for initiating crosslinking of the photocrosslinkable groups when exposed to a light source of a suitable wavelength and intensity; and a suitable organic solvent. This document describes a photocrosslinkable precursor polymer in which each repeat unit comprises one photocrosslinkable moiety and an aromatic group X. The aromatic group X can be selected among several alternatives, possibly comprising linking moieties to be also selected among several alternatives. The presently claimed structure, notably the PAES/PAEK blocks, is neither individualized nor exemplified in this document.

Hegde, et al. “3D printing all-aromatic high-performance polyimides using μSLA: Processing the non-processable” (252nd ACS National Meeting & Exposition, Aug. 21-25, 2016) and Hedge et al. “3D Printing All-Aromatic Polyimides using Mask-Projection Stereolithography: Processing the Nonprocessable” (Adv. Mater. 2017, 29, published on Jun. 19, 2017), disclose 3D printing of a polyamic diacrylate ester (PADE) in which each repeating unit derives from 4,4′-oxydianiline (ODA) and pyromellitic dianhydride, and contains two photo-crosslinkable acrylate groups.

Herzberger et al. “3D Printing All-Aromatic Polyimides Using Stereolithographic 3D Printing of Polyamic Acid Salts” (ACS Macro Lett., 2018, 7 (4), pp 493-497) describes 3D printing of polyamic acid (PAA) structures derived from 4,4′-oxydianiline (ODA) and pyromellitic dianhydride, and containing 2-(dimethylamino)ethyl methacrylate.

There is a need for polymerizable polymers and compositions to be used in lithographic processes which are capable of producing 3D articles that possess good mechanical properties after photofabrication while also retaining their mechanical properties after exposure to high temperature and light, for example above 150° C. There is also a need for polymerizable polymers and compositions well-suited for high temperature 3D printing processes, notably that are thermally stable at temperatures required to melt the polymers. The present invention relates to a polymer that is soluble, photo reactive, and can convert into a thermally stable sulfone following photo reaction via imidization of the linkages.

### DISCLOSURE OF THE INVENTION

According to a first aspect, the present invention relates to poly(aryl ether) (PAE) polymers, which can for example be used in lithographic processes for the photofabrication of three-dimensional (3D) articles.

Stereolithography is an additive manufacturing process that works by focusing light, for example an ultraviolet (UV) light or visible light, on a vat of crosslinkable photopolymer resin. Then complex three-dimensional (3D) structures can be built in a layer-by-layer fashion.

The PAE polymer of the present invention may notably be liquid, in the form of a powder or pellets.

The PAE polymer of the invention is based on poly(aryl ether sulfone) (PAES) recurring units and/or on poly(aryl ether ketone) (PAEK) recurring units. The PAE polymer of the invention can be 3D printed to manufacture articles, for example using the stereolithography technology (SLA), the ink-jet technology, direct ink writing (DIW) or digital light processing (DLP). Since the PAE polymer contains recurring units of PAES and/or PAEK, the printed material has been shown to exhibit properties, notably mechanical properties, similar to PAES or PAEK polymers as such.

The poly(aryl ether) (PAE) polymer (P1) also comprises at least one group (L) according to formula (L1) to (L4) below:

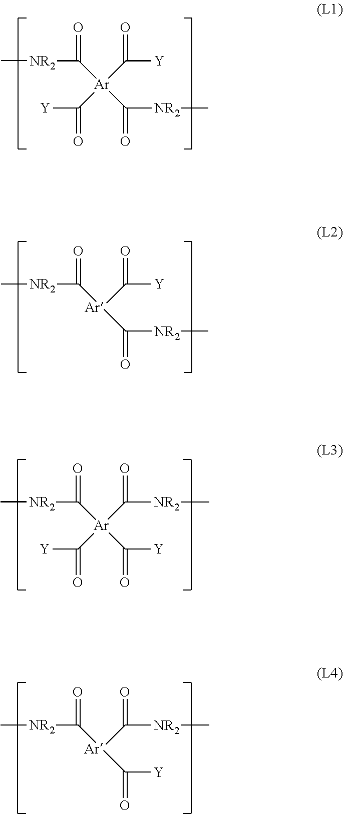

in which Ar and Ar′ are respectively tetravalent or trivalent aromatic moiety selected from the group consisting of a substituted or unsubstituted, saturated, unsaturated or aromatic monocyclic and polycyclic group having 5 to 50 carbon atoms, and in which Y is a group which may optionally be removed during the 3D printing process or after printing as a post-printing step involving thermo-curring.

In some embodiments, the PAE polymer (P1) of the invention is such that it comprises:
at least two groups (L), at least three groups (L), at least four groups (L), at least five groups (L) per polymer unit, and/or
less than 20 groups (L), less than 15 groups (L), less than 12 groups (L), less than 10 groups (L).

In some embodiments, the PAE polymer (P1) of the invention is such that it comprises from one group (L) each two recurring units to one group (L) each forty recurring units. Preferably, the PAE polymer (P1) of the invention comprises from one group (L) each five recurring units to one group (L) each thirty recurring units. More preferably, the PAE polymer (P1) of the invention comprises from one group (L) each six recurring units to one group (L) each twenty recurring units. Even more preferably, the PAE polymer (P1) of the invention comprises from one group (L) each eight recurring units to one group (L) each fifteen recurring units.

The PAE polymer (P1) of the invention is such that, in formulas (L1) and (L2) above, each Y is independently selected from the group consisting of:
O—(CH₂)ₖ—O—CO—CH═CHR₄, with k being from 1 to 20, preferably from 1 to 8, more preferably from 2 to 6, even more preferably equal to 2 or 3; and R₄ being H or an alkyl, preferably an alkyl having 1 to 5 carbon atoms,
O—(CH₂)—Ar—CR₅═CHR₆ or O—(CH₂)—OAr—CRS═CHR₆, wherein p is from 0 to 20, preferably from 1 to 8; Ar comprises one or two aromatic or heteroaromatic rings; R₅ and R₆ are H, an alkyl, preferably an alkyl having 1 to 5 carbon atoms, a phenyl or a COOR₇ with R₇ being H or an alkyl, preferably an alkyl having 1 to 5 carbon atoms,
O—(CH₂)_{q}—CH═CHR₈ with q being from 0 to 20, preferably from 1 to 8; and R₈ being H or an alkyl, preferably an alkyl having 1 to 5 carbon atoms;
O—(CH₂)ᵣO—CH═CHR₉ with r being from 0 to 20, preferably from 1 to 8; and R₉ being H or an alkyl, preferably an alkyl having 1 to 5 carbon atoms;

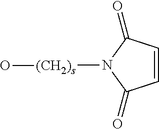

with s being from 0 to 20, preferably from 1 to 8;
O⁻, NRₐR_{b}R_{c}H⁺—(CH₂)ₖ O—CO—CH═CHR₄, with k and R₄ as above-defined;
O⁻, NRₐR_{b}R_{c}H⁺—(CH₂)P—Ar—CR₅═CHR₆ with p, Ar, R₅ and R₆ as above-defined;
O⁻, NRₐR_{b}R_{c}H⁺—(CH₂)P—OAr—CR₅═CHR₆ with p, Ar, R₅ and R₆ as above-defined;
O⁻, NRₐR_{b}R_{c}H⁺—(CH₂)_{q}—CH═CHR₈, with q and R₈ as above-defined;
O⁻, NRₐR_{b}R_{c}H⁺—(CH₂)ᵣ—O—CH═CHR₉, with r and R₉ as above-defined;

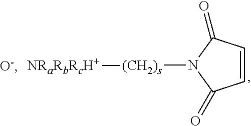

with s as above-defined;
wherein Rₐ, R_{b}, and R_{c} are independently H or an alkyl, preferably an alkyl having from 1 to 5 carbon atoms.

In some embodiments, the PAE polymer (P1) is such that Y is O—(CH₂)ₖ—O—CO—CH═CHR₄, with k is between 2 and 6, preferably equal to 2 or 3, and R₄ is H or CH₃.

The recurring units R_{PAES} and/or recurring units R_{PAEK} may be in blocks and comprise at least two recurring units, for example at least three, at least four, at least five or at least six recurring units. The blocks may for example comprise between 1 and 40 recurring units, preferably between 2 and 30 recurring units, more preferably between 3 and 20 recurring units. The number average molecular weight of the blocks may for example vary between 800 g/mol and 15,000 g/mol, between 1,000 and 12,000 g/mol, between 1,500 and 10,000 g/mol (as measured by gel permeation chromatography (GPC) using N,N dimethyl formamide (DMF) as a mobile phase, with polystyrene standards).

The PAE polymer (P1) may preferably have a number average molecular weight (Mn) (as measured by gel permeation chromatography (GPC) using N,N dimethyl formamide (DMF) as a mobile phase, with polystyrene standards) of:
less than 100,000 g/mol, less than 80,000 g/mol or less than 60,000 g/mol; and/or
more than 1,000 g/mol, more than 2,000 g/mol or more than 3,000 g/mol.

According to an embodiment, the PAE polymer (P1) of the present invention has a Tg ranging from 100 and 250° C., preferably from 120 and 240° C., more preferably from 130 and 230° C., as measured by differential scanning calorimetry (DSC) according to ASTM D3418. When the PAE polymer (P10 of the present invention comprises PAEK recurring units, the Tg preferably ranges between 100 and 180° C., for example between 120 and 160° C.

According to a second aspect of the present invention, the PAE polymer (P1) described above may be incorporated in a formulation (F) to be used in photofabrication processes. In particular, the polymer (P1) and formulation (F) of the present invention can be incorporated into lithographic processes in which light is used to cure or crosslink the functionalized polymers.

The formulation (F) of the present invention also comprises:
at least one solvent,
optionally at least one photoinitiator, and
optionally at least one blocker.

The formulation (F) of the present invention is preferably liquid, for example at room temperature or above.

The formulation (F) can have a large viscosity range, which depends on the type of 3D printing method used. For example the viscosity of the formulation (F) may vary between 0.01 and 10,000 Pa·s. The viscosity of the formulation (F) preferably ranges between 0.01 and 10 Pa·s when the object is printed via stereolithography (SLA). The viscosity of the formulation (F) preferably ranges between 10 and 10,000 Pa·s when the object is printed via direct ink writing (DIW). The viscosity of the formulation (F) is preferably less than 0.1 Pa·s when the object is printed via ink-jetting.

According to the present invention, a photoinitiator is a compound especially added to a formulation to convert absorbed light energy, UV or visible light, into chemical energy in the form of initiating species, for example free radicals or cations.

According to the present invention, a blocker is a compound added to either scavenge unused radicals created by the photoinitiator or absorb a portion of the incident light energy, for example UV light and visible light. This compound allows for improving dimensional accuracy of the fabricated part.

The formulation (F) of the present invention can comprise more than one polymer (P1), for example two of three distinct polymers (P1).

Poly(aryl ethersulfone) (PAES)

According to a first embodiment, P1 is a PAES having recurring units (R_{PAES}) of formula (M):

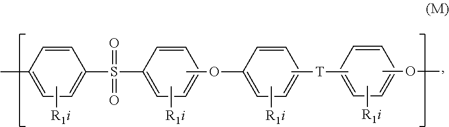

in which
each R₁ is independently selected from the group consisting of a halogen, alkyl, alkenyl, alkynyl, aryl, ether, thioether, carboxylic acid, ester, amide, imide, alkali or alkaline earth metal sulfonate, alkyl sulfonate, alkali or alkaline earth metal phosphonate, alkyl phosphonate, amine and quaternary ammonium;
each i is an independently selected from 0 to 4 for each aromatic cycle;
T is selected from the group consisting of a bond, —CH₂—; —O—; —SO₂—; —S—;
—C(O)—; —C(CH₃)₂—; —C(CF₃)₂—; —C(═CCl₂)—; —C(CH₃)(CH₂CH₂COOH)—; —N═N—;
—RₐC═CR_{b}—, where each Rₐ and R_{b}, independently of one another, is a hydrogen or a C1-C12-alkyl, C1-C12-alkoxy, or C6-C18-aryl group;
—(CH₂)ₘ— and —(CF₂)ₘ— with m being an integer from 1 to 6; an aliphatic divalent group, linear or branched, of up to 6 carbon atoms; and combinations thereof.

According to a preferred embodiment of the present invention, P1 is a PAES wherein T is selected from the group consisting of a bond, —SO₂— and —C(CH₃)₂—.

The polymer P1 may for example be a PAES comprising at least 50 mol. % (based on the total number of moles in the polymer) of recurring units selected from the group consisting of formulas:

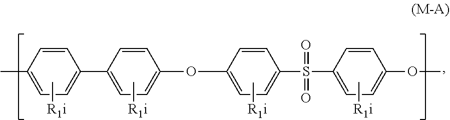

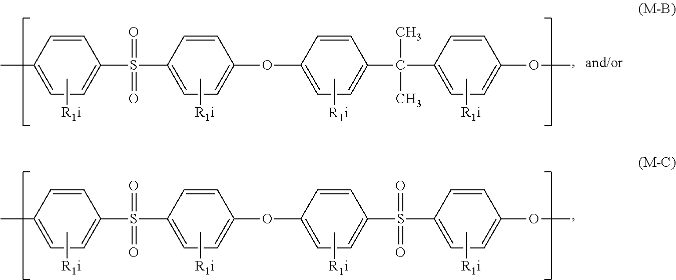

wherein R₁ and i are as above-mentioned.

According to this embodiment, at least 60 mol. %, at least 70 mol. %, at least 80 mol. %, at least 90 mol. %, at least 95 mol. %, at least 99 mol. % (based on the total number of moles in the polymer) or all of the recurring units in the PAES are recurring units (R_{PAES}) of formula (M-A), formula (M-B) and/or formula (M-C).

According to an embodiment, P1 is a PAES wherein T is a bond. In other words, P1 is a poly(biphenyl ether sulfone) (PPSU)-based polymer.

According to an embodiment, P1 is a PPSU comprising at least 50 mol. % of the recurring units are recurring units (R_{PPSU}) of formula (M-A):

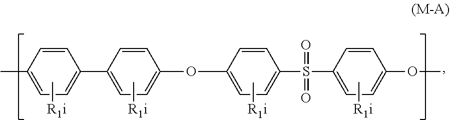

(the mol. % being based on the total number of moles in the polymer), wherein R₁ and i are as above-mentioned.

According to an embodiment, P1 is a PAES wherein T is —C(CH₃)₂—. In other words, P is a polysulfone (PSU)-based polymer.

According to an embodiment, P1 is a PSU comprising at least 50 mol. % of the recurring units are recurring units (R_{PSU}) of formula (M-B):

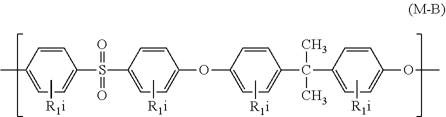

(the mol. % being based on the total number of moles in the polymer), wherein R₁ and i are as above-mentioned.

The PPSU or PSU polymer can therefore be homopolymers or copolymers. If they are copolymers, they can be random, alternate or block copolymers.

Poly(aryl ether ketone) (PAEK)

According to a second embodiment, P1 is a PAEK having recurring units R_{PAEK} selected from the group consisting of units of formulas (J-A) to (J-D):

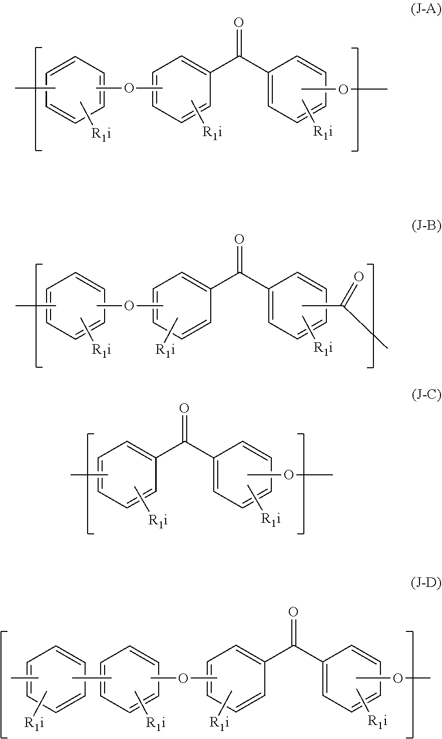

wherein:
each R₁ is independently selected from the group consisting of a halogen, alkyl, alkenyl, alkynyl, aryl, ether, thioether, carboxylic acid, ester, amide, imide, alkali or alkaline earth metal sulfonate, alkyl sulfonate, alkali or alkaline earth metal phosphonate, alkyl phosphonate, amine and quaternary ammonium; and
each i is an independently selected from 0 to 4 for each aromatic cycle.

In the recurring units (R_{PAEK}), the phenylene moieties may independently have 1,2-, 1,4- or 1,3-linkages to the other phenylene moieties. Preferably, the phenylene moieties have 1,3- or 1,4-linkages, more preferably they have a 1,4-linkage.

In the recurring units (R_{PAEK}), i is preferably zero so that the phenylene moieties have no other substituents than those linking the main chain of the polymer.

The PAEK described here may be semi-crystalline or amorphous. The term “semi-crystalline polymer” refers to a polymer capable of exhibiting an average percent crystallinity in a solid state of at least about 10% by weight when allowed to crystallize to its fullest extent. The term “semi-crystalline polymer” includes polymeric materials capable of having crystallinities up to 100% (i.e., fully-crystalline polymeric materials). The term “amorphous polymer” refers to a polymer that is not a semi-crystalline polymer.

According to an embodiment, P1 is an amorphous PAEK, preferably a amorphous PEEK-based polymer.

According to an embodiment, P1 is a PAEK comprising recurring units (R_{PAEK}) according to formula (J-A). In other words, P1 is a poly(ether ether ketone) (PEEK)-based polymer.

According to another embodiment of the present invention, P1 is a PAEK comprising at least 50 mol. % (based on the total number of moles in the polymer) of recurring units (R_{PEEK}) according to formula (J-A):

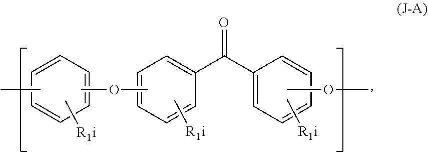

wherein R₁ and i are as above-described.

According to formula (J-A), each aromatic cycle of the recurring unit (R_{PEEK}) may contain from 1 to 4 radical groups R′. When i is 0, the corresponding aromatic cycle does not contain any radical group R₁.

Each phenylene moiety of the recurring unit (R_{PEEK}) may, independently from one another, have a 1,2-, a 1,3- or a 1,4-linkage to the other phenylene moieties. According to an embodiment, each phenylene moiety of the recurring unit (R_{PEEK}), independently from one another, has a 1,3- or a 1,4-linkage to the other phenylene moieties. According to another embodiment yet, each phenylene moiety of the recurring unit (R_{PEEK}) has a 1,4-linkage to the other phenylene moieties.

According to an embodiment, R₁ is, at each location in formula (J-A) above, independently selected from the group consisting of a C1-C12 moiety, optionally comprising one or more than one heteroatoms; sulfonic acid and sulfonate groups; phosphonic acid and phosphonate groups; amine and quaternary ammonium groups.

According to an embodiment, i is zero for each R₁. In other words, according to this embodiment, the recurring units (R_{PEEK}) are according to formula (J′-A):

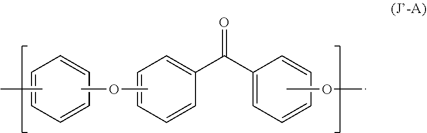

According to another embodiment of the present disclosure, a poly(ether ether ketone) (PEEK) denotes any polymer comprising at least 10 mol. % of the recurring units are recurring units (R_{PEEK}) of formula (J-A″):

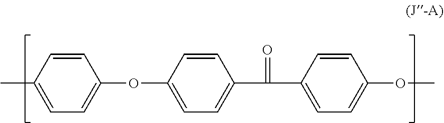

the mol. % being based on the total number of moles of recurring units in the polymer.

According to an embodiment of the present disclosure, at least 10 mol. % (based on the total number of moles of recurring units in the polymer), at least 20 mol. %, at least 30 mol. %, at least 40 mol. %, at least 50 mol. %, at least 60 mol. %, at least 70 mol. %, at least 80 mol. %, at least 90 mol. %, at least 95 mol. %, at least 99 mol. % or all of the recurring units in the PEEK are recurring units (R_{PEEK}) of formulas (J-A), (J′-A) and/or (J″-A).

The PEEK polymer can therefore be a homopolymer or a copolymer. If the PEEK polymer is a copolymer, it can be a random, alternate or block copolymer.

When the PEEK is a copolymer, it can be made of recurring units (R*_{PEEK}) different from and in addition to recurring units (R_{PEEK}), such as recurring units of formula (J-D).

According to an embodiment, P1 is an amorphous PAEK, preferably an amorphous PEEK-based polymer.

According to an embodiment, P1 is a PAEK comprising recurring units (R_{PAEK}) according to formula (J-B). In other words, P1 is a poly(ether ketone ketone) (PEKK)-based polymer.

According to another embodiment of the present invention, P1 is a PAEK comprising at least 50 mol. % (based on the total number of moles in the polymer) of recurring units (R_{PEKK}) according to formula (J-B):

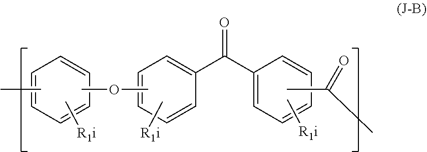

wherein R₁ and i are as above-described.

According to another embodiment, i is zero for each R₁.

According to one embodiment, P1 is a PAEK comprising at least 50 mol. % of recurring units of formulas (J-B₁) and (J-B₂), the mol. % being based on the total number of moles of recurring units in the polymer:

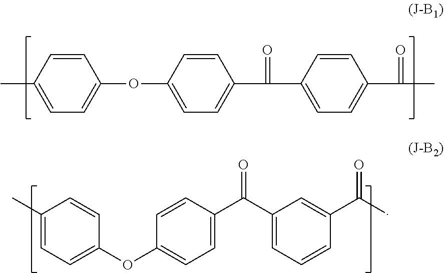

According to an embodiment of the present disclosure, at least 60 mol. %, at least 70 mol. %, at least 80 mol. %, at least 90 mol. %, at least 95 mol. %, at least 99 mol. % or all of the recurring units in the PEKK are recurring units (R_{PEKK}) of formulas (J-B), (J-B₁) and/or (J-B₂).

According to an embodiment of the present disclosure, in the PEKK polymer, the molar ratio of recurring units (J-B₂) to recurring units (J-B₁) is at least 1:1 to 5.7:1, for example at least 1.2:1 to 4:1, at least 1.4:1 to 3:1 or at least 1.4:1 to 1.86:1.

Solvent

The concentration of the solvent may be between 1 to 80 wt. %, based on the total weight of the formulation (F), for example between 2 and 75 wt. %, between 5 and 70 wt. % or between 10 and 65 wt. %.

According to an embodiment of the present invention, the solvent is selected from the group consisting of N-methylpyrrolidone (NMP), N,Ndimethylformamide (DMF), N,N-dimethylacetamide (DMAC), 1,3-dimethyl-2-imidazolidinone, tetrahydrofuran (THF), dimethyl sulfoxide (DMSO) and sulfolane.

Preferably, the solvent is a dipolar aprotic solvent. Preferably, the solvent is selected from the group consisting of N-methylpyrrolidone (NMP), dimethylacetamide (DMAc or DMA), N-Cyclohexyl-2-pyrrolidone (CH P) and dimethyl sulfoxide (DMSO).

Photoinitiator

According to the present invention, the photoinitiator is a compound especially added to a formulation to convert absorbed light energy, UV or visible light, into chemical energy in the form of initiating species, for example free radicals or cations. Based on the mechanism by which initiating radicals are formed, photoinitiators are generally divided into two classes:
Type I photoinitiators undergo a unimolecular bond cleavage upon irradiation to yield free radicals,
Type II photoinitiators undergo a bimolecular reaction where the excited state of the photoinitiator interacts with a second molecule (a coinitiator) to generate free radicals.

The concentration of the photoinitiator in the formulation (F) may be between 0.05 to 10 wt. %, based on the total weight of the formulation (F), for example between 0.1 and 5 wt. %, between 0.2 and 4 wt. % or between 0.5 and 3 wt. %.

According to an embodiment of the present invention, the photoinitiator is selected from the group consisting of:
Acetophenone
Anisoin
Anthraquinone
Anthraquinone-2-sulfonic acid, sodium salt monohydrate
(Benzene) tricarbonylchromium
Benzil
Benzoin
Benzoin ethyl ether, Benzoin isobutyl ether, Benzoin methyl ether and Benzophenone
3,3′,4,4′-Benzophenonetetracarboxylic dianhydride
4-Benzoylbiphenyl
2-Benzyl-2-(dimethylamino)-4′-morpholinobutyrophenone
4,4′-Bis(diethylamino)benzophenone
4,4′-Bis(dimethylamino)benzophenone
Camphorquinone
2-Chlorothioxanthen-9-one
(Cumene)cyclopentadienyliron(II) hexafluorophosphate
Dibenzosuberenone
2,2-Diethoxyacetophenone
4,4′-Dihydroxybenzophenone
2,2-Dimethoxy-2-phenylacetophenone
4-(Dimethylamino)benzophenone
4,4′-Dimethylbenzil
2,5-Dimethylbenzophenone
3,4-Dimethylbenzophenone
Diphenyl(2,4,6-trimethylbenzoyl)phosphine oxide, 2-Hydroxy-2-methylpropiophenone and blends (e.g. 50/50 blend)
4′-Ethoxyacetophenone
2-Ethylanthraquinone
Ferrocene
3′-Hydroxyacetophenone, 4′-Hydroxyacetophenone, 3-Hydroxybenzophenone and 4-Hydroxybenzophenone
1-Hydroxycyclohexyl phenyl ketone
2-Hydroxy-2-methylpropiophenone
2-Methylbenzophenone or 3-Methylbenzophenone
Methybenzoylformate
2-Methyl-4′-(methylthio)-2-morpholinopropiophenone
Phenanthrenequinone
4′-Phenoxyacetophenone
Phenylbis(2,4,6-trimethylbenzoyl)phosphine oxide
Thioxanthen-9-one
Triarylsulfonium hexafluoroantimonate salts, mixed, 50% in propylene carbonate
Triarylsulfonium hexafluorophosphate salts, mixed, 50% in propylene carbonate,
2,4,5,7-Tetraiodo-3-hydroxy-9-cyano-6-fluorone
2,4,5,7-Tetraiodo-3-hydroxy-6-fluorone
5,7-diiodo-3-butoxy-6-fluorone, and
mixtures thereof.

Preferably, the photoinitiator is selected from the group consisting of 2,2-dimethoxy-2-phenylacetophenone (DMPA), Diphenyl(2,4,6-trimethylbenzoyl)phosphine oxide and Phenylbis(2,4,6-trimethylbenzoyl)phosphine oxide.

Blocker

According to the present invention, a blocker is a compound that is added to the formulation in order to (i) scavenge a predetermined amount of radicals formed by the photoinitiator while irradiated by UV light, (ii) scavenge unused radicals that may be present after the UV irradiation source has been turned off, and/or (iii) absorb a portion of the energy that is delivered to the system during UV irradiation.

The concentration of the blocker in the formulation (F) may be between 0.05 to 10 wt. %, based on the total weight of the formulation (F), for example between 0.1 and 5 wt. %, between 0.2 and 4 wt. % or between 0.5 and 3 wt. %.

According to an embodiment of the present invention, the blocker is selected from the group consisting of:
2-hydroxy-4-methoxy benzophenone (oxybenzene)
1-(4-methoxyphenyl)-3-(4-tert-butylphenyl)propane-1,3-dione (avobenzone)
disodium 2,2′-(1,4-phenylene)bis(6-sulfo-1H-benzimidazole-4-sulfonate) (bisdisulizole disodium)
hexyl 2-[4-(diethylamino)-2-hydroxybenzoyl]benzoate (diethylamino hydroxybenzoyl hexyl benzoate)
menthyl-o-aminobenzoate (menthyl anthranilate)
2,2′-[6-(4-methoxyphenyl)-1,3,5-triazine-2,4-diyl] bis{5-[(2-ethylhexyl)oxy]phenol}(bemotrizinol)
2,4-dihydroxybenzophenone
2,2′,4,4′-tetrahydroxybenzophenone
4-Hydroxy-2-methoxy-5-(oxo-phenylmethyl)benzenesulfonic acid (sulisobenzone)
2,2′-dihydroxy-4,4′-dimethoxybenzophenone
5-chloro-2-hydroxybenzophenone
(2-hydroxy-4-methoxyphenyl)-(2-hydroxyphenyl)methanone (dioxybenzone)
2,5-Bis(5-tert-butyl-benzoxazol-2-yl)thiophene
sodium 2,2′-dihydroxy-4,4′-dimethoxybenzophenone-5,5′-disulfonate
(2-hydroxy-4-methoxyphenyl)(4-methylphenyl)methanone (mexenone)
(2-hydroxy-4-octoxy-phenyl)-phenyl-methanone (octabenzone)
2-(1,2,3-Benzotriazol-2-yl)-4-methyl-6-[2-methyl-3-(2,2,4,6,6-pentamethyl-3,5-dioxa-2,4,6-trisilaheptan-4-yl) propyl]phenol (drometrizole trisiloxane)
terephthalylidene dicamphor sulfonic acid (ecamsule)
2-ethylhexyl 2-cyano-3,3-diphenyl-2-propenoate (octocrylene)
diethylhexyl butamido triazone (iscotrizinole)
2-Ethoxyethyl 3-(4-methoxyphenyl)propenoate (cinoxate)
isopentyl 4-methoxycinnamate (amiloxate)
2,2′-methanediylbis[6-(2H-benzotriazol-2-yl)-4-(2,4,4-trimethylpentan-2-yl) phenol](bisoctrizole)
2-(2H-benzotriazol-2-yl)-4-(1,1,3,3-tetramethylbutyl)phenol
2,2′-methylenebis[6-(2H-benzotriazol-2-yl)-4-(1,1,3,3-tetramethylbutyl) phenol]
2-hydroxy-4-(octyloxy)benzophenone
2-ethyl-, 2-[4-(4,6-diphenyl-1,3,5-triazin-2-yl)-3-hydroxyphenoxy]ethyl ester 2-tert-butyl-6-(5-chloro-2H-benzotriazol-2-yl)-4-methylphenol
2-(2-hydroxy-5-methylphenyl)benzotriazole
2,4-dinitrophenylhydrazine
N-(4-ethoxycarbonylphenyl)-N′-methyl-N′-phenylformamidine
hexadecyl 3,5-bis-tert-butyl-4-hydroxybenzoate
2-ethyl-2′-ethoxy-oxalanilide, and
mixture thereof.

Preferably, the blocker is selected from the group consisting of avobenzone and 2,5-Bis(5-tert-butyl-benzoxazol-2-yl)thiophene.

Optional Components

The formulation of the present invention may comprise at least one additive, for example selected from the group consisting of fillers such as silica, antioxidants, antibacterial compounds and antistatic compounds. The additive may for example be a chemically inert species such as carbon black, silica (e.g. microsilica particles) and carbon nano tubes.

According to a third aspect of the present invention, the PAE polymer (P1) described above may be incorporated in a composition (C).

The composition (C) may comprise the PAE polymer (P1) in an amount of at least 1 wt. %, for example at least 5 wt. %, at least 10 wt. %, at least 15 wt. %, at least 20 wt. %, at least 25 wt. %, or at least 30 wt. %, based on the total weight of the composition (C).

The composition (C) may comprise the PAE polymer (P1) in an amount of more than 50 wt. %, for example more than 55 wt. %, more than 60 wt. %, more than 65 wt. %, more than 70 wt. %, more than 75 wt. %, more than 80 wt. %, more than 85 wt. %, more than 90 wt. %, more than 95 wt. % or more than 99 wt. %, based on the total weight of the composition (C).

According to an embodiment, the composition (C) comprises the PAE polymer (P1) in an amount ranging from 1 to 99 wt. %, for example from 3 to 96 wt. %, from 6 to 92 wt. % or from 12 to 88 wt. %, based on the total weight of the composition (C).

The composition (C) may further optionally comprise one or more additional additives selected from the group consisting of light stabilizers (for example UV light stabilizers), photosensitizers, heat stabilizers, acid scavengers (i.e. zinc oxide, magnesium oxide), antioxidants, pigments, processing aids, lubricants, flame retardants, and/or conductivity additive (i.e. carbon black and carbon nanofibrils).

The composition (C) may also further comprise other polymers than the PAE polymer (P1) of the present invention, for example sulfone polymer, e.g. poly(biphenyl ether sulfone) (PPSU), polysulfone (PSU), polyethersulfone (PES), or a polyphenylene sulfide (PPS), a poly(aryl ether ketone) (PAEK), e.g. a poly(ether ether ketone) (PEEK), a polyamide-imide (PAI), a polyimide (PI), a polyphenylene (SRP), a poly(ether ketone ketone) (PEKK), a poly(ether ketone) (PEK) or a copolymer of PEEK and poly(diphenyl ether ketone) (PEEK-PEDEK copolymer), a polyetherimide polymer (PEI), and/or polycarbonate (PC).

The composition (C) may further comprise flame retardants such as halogen and halogen free flame retardants.

The composition (C) may comprise glass fibers, for example E-glass fibers or high modulus glass fibers having an elastic modulus (also called tensile modulus of elasticity) of at least 76, preferably at least 78, more preferably at least 80, and most preferably at least 82 GPa as measured according to ASTM D2343. The composition (C) may also comprise high modulus glass fibers selected from the group consisting of R, S and T glass fibers, for example in an amount of at least 5 wt. %, for example at least 10 wt. %, at least 15 wt. %, at least 20 wt. %, at least 25 wt. %, at least 26 wt. %, or at least 28 wt. %, based on the total weight of the composition (C). The composition (C) may comprise circular cross-section glass fibers and/or non-circular cross-section glass fibers (e.g. flat, rectangular, cocoon-shaped glass fibers).

The composition (C) may comprise carbon fibers, graphene or carbon nanotubes.

The composition (C) can be made by methods well known to the person skilled in the art. For example, such methods include, but are not limited to, melt-mixing processes. Melt-mixing processes are typically carried out by heating the polymer components above the melting temperature of the thermoplastic polymers thereby forming a melt of the thermoplastic polymers. In some embodiments, the processing temperature ranges from about 280-450° C., preferably from about 290-400° C., from about 300-360° C. or from about 310-340° C. Suitable melt-mixing apparatus are, for example, kneaders, Bradbury mixers, single-screw extruders, and twin-screw extruders. Preferably, use is made of an extruder fitted with means for dosing all the desired components to the extruder, either to the extruder's throat or to the melt. The components of the polymer composition are fed to the melt-mixing apparatus and melt-mixed in that apparatus. The components may be fed simultaneously as a powder mixture or granule mixer, also known as dry-blend, or may be fed separately.

According to a fourth aspect, the present invention also relates to a process for preparing the PAE polymer (P1) of the present invention.

According to a first embodiment, the process for preparing the PAE polymer (P1) comprises at least the following two steps:
a) providing a PAE polymer (P0) of formula RₙRₘN—P—NRₙRₘ, wherein P comprises recurring units R_{PAES} and/or recurring units R_{PAEK}, as above described, and each Rₙ and Rₘ is independently H or an alkyl, preferably H or an alkyl having 1 to 5 carbon atoms;
b) reacting the PAE polymer (P0) with a compound of formula (I), (II), (Ill) or (IV):

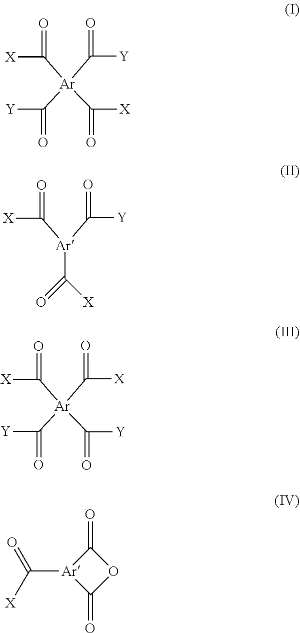

wherein:
Ar is a tetravalent aromatic moiety, selected from the group consisting of a substituted or unsubstituted, saturated, unsaturated or aromatic monocyclic and polycyclic group having 5 to 50 carbon atoms;
Ar′ is a trivalent aromatic moiety selected from the group consisting of a substituted or unsubstituted, saturated, unsaturated or aromatic monocyclic and polycyclic group having 5 to 50 carbon atoms;
X is Cl, Br, F or I;
each Y is independently selected from the group consisting of:
   O—(CH₂)ₖ—O—CO—CH═CHR₄, with k being from 1 to 20, preferably from 1 to 8, more preferably from 2 to 6, even more preferably equal to 2 or 3; and R₄ being H or an alkyl, preferably an alkyl having 1 to 5 carbon atoms,
   O—(CH₂)—Ar—CR₅═CHR₆ or O—(CH₂)—OAr—CRS═CHR₆, wherein p is from 0 to 20, preferably from 1 to 8; Ar comprises one or two aromatic or heteroaromatic rings; R₅ and R₆ are H, an alkyl, preferably an alkyl having 1 to 5 carbon atoms, a phenyl or a COOR₇ with R₇ being H or an alkyl, preferably an alkyl having 1 to 5 carbon atoms,
   O—(CH₂)_{q}—CH═CHR₈ with q being from 0 to 20, preferably from 1 to 8; and R₈ being H or an alkyl, preferably an alkyl having 1 to 5 carbon atoms;
   O—(CH₂)ᵣ—O—CH═CHR₉ with r being from 0 to 20, preferably from 1 to 8; and R₉ being H or an alkyl, preferably an alkyl having 1 to 5 carbon atoms;

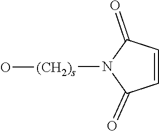

with s being from 0 to 20, preferably from 1 to 8;
O⁻, NRₐR_{b}R_{c}H⁺—(CH₂)ₖ O—CO—CH═CHR₄, with k and R₄ as above-defined;
O⁻, NRₐR_{b}R_{c}H⁺—(CH₂)ₚ-Ar—CR₅═CHR₆ with p, Ar, R₅ and R₆ as above-defined;
O⁻, NRₐR_{b}R_{c}H⁺—(CH₂)P—OAr—CR₅═CHR₆ with p, Ar, R₅ and R₆ as above-defined;
O⁻, NRₐR_{b}R_{c}H⁺—(CH₂)_{q}—CH═CHR₈, with q and R₈ as above-defined;
O⁻, NRₐR_{b}R_{c}H⁺—(CH₂)ᵣ—O—CH═CHR₉, with r and R₉ as above-defined;

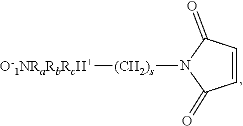

with s as above-defined;
wherein Rₐ, R_{b}, and R_{c} are independently H or an alkyl, preferably an alkyl having from 1 to 5 carbon atoms,
in the presence of a polar aprotic solvent and an organic base.

The polymer PAE (P0) is according to formula RₙRₘN—P—NRₙRₘ. Preferably, Rₙ and Rₘ are H and P0 is according to formula H₂N—P—NH₂.

In embodiments wherein the amine moieties (NRₙRₘ or NH₂) are link to the polymer P via a phenylene group (C₆H₆), the amine moieties may be in position ortho (1,2-aminophenyl), meta (1,3-aminophenyl), or para (1,4-aminophenyl) with respect to the polymer chain P, preferably in position para (1,4-aminophenyl) with respect to the carbon chain P.

According to an embodiment, the polar aprotic solvent is selected from the group consisting of chlorobenzene, chloroform, N-methylpyrrolidone (NMP), N,Ndimethylformamide (DMF), N,N-dimethylacetamide (DMAC), 1,3-dimethyl-2-imidazolidinone, tetrahydrofuran (THF), dimethyl sulfoxide (DMSO) and sulfolane.

According to an embodiment, the organic base is selected from the group consisting of pyridine and alkylamine, for example trimethylamine.

According to a second embodiment, the process for preparing the PAE polymer (P1) comprises at least the following three steps:
a) providing a PAE polymer (P0) of formula RₙRₘN—P—NRₙRₘ, wherein P comprises recurring units R_{PAES} and/or recurring units R_{PAEK}, wherein as above described, and each Rₙ and Rₘ is independently H or an alkyl, preferably H or an alkyl having 1 to 5 carbon atoms;
b) reacting the PAE polymer (P0) with a compound of formula (IV), (V), (VI) or (VII):

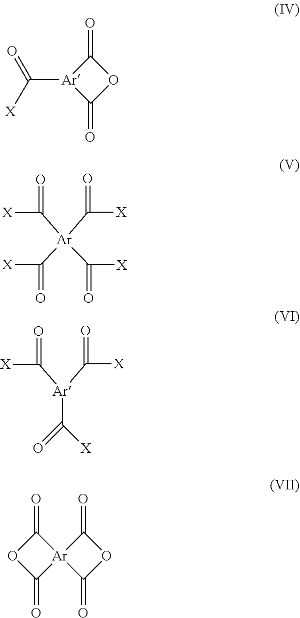

wherein:
Ar is a tetravalent aromatic moiety, selected from the group consisting of a substituted or unsubstituted, saturated, unsaturated or aromatic monocyclic and polycyclic group having 5 to 50 carbon atoms;
Ar′ is a trivalent aromatic moiety selected from the group consisting of a substituted or unsubstituted, saturated, unsaturated or aromatic monocyclic and polycyclic group having 5 to 50 carbon atoms;
X is OH, Cl, Br, F or I;
c) reacting the polymer obtained in step b) with a compound selected from the group consisting of:
NRₐR_{b}R_{c}—(CH₂)ₖ—O—CO—CH═CHR₄, with k and R₄ as above-defined,
NRₐR_{b}R_{c}—(CH₂)—Ar—CR₅═CHR₆ with p, Ar, R₅ and R₆ as above-defined,
NRₐR_{b}R_{c}—(CH₂)—OAr—CR₅═CHR₆ with p, Ar, R₅ and R₆ as above-defined,
NRₐR_{b}R_{c}—(CH₂)_{q}—CH═CHR₈, with q and R₈ as above-defined,
NRₐR_{b}R_{c}—(CH₂)ᵣ—O—CH═CHR₉, with r and R₉ as above-defined,

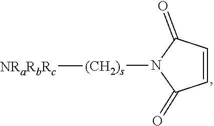

with s as above-defined,
wherein Rₐ, R_{b}, and R_{c}, are independently H or an alkyl, preferably an alkyl having from 1 to 5 carbon atoms.

According to a fifth aspect, the present invention also relates to a method for manufacturing a 3D article with an additive manufacturing system, comprising:
providing a polymer formulation (F) as above-described,
printing layers of the 3D article from the polymer formulation (F),
optionally, curing the 3D article at a temperature ranging from 100 to 300° C., preferably from 120 to 280° C.

According to an embodiment, the step of printing comprises irradiating the polymer formulation (F), for example a layer of such formulation (F) deposited onto the printing surface, with light. For example, with UV light, the layer preferably presents a size in the range of 5 μm to 300 μm, for example 20 μm to 150 μm.

The light can for example be laser light. The irradiation is preferably of sufficient intensity to cause substantial curing of the polymer formulation (F), for example the layer of such formulation (F). Also, the irradiation is preferably of sufficient intensity to cause adhesion of the layers of polymer formulation (F).

According to another embodiment of the present invention, the method for manufacturing a 3D article with an additive manufacturing system, comprises the steps of:
providing a polymer formulation (F) as above-described,
printing layers of the 3D article from the polymer formulation (F) by:
a) coating a layer of the formulation (F) onto a surface,
b) irradiating the layer with light, for example UV light or visible light,
c) coating a layer of the formulation (F) onto the former irradiated layer,
d) irradiating the layer with light, for example UV light or visible light, and
e) repeating steps c) and d) a sufficient number of times to manufacture the 3D article.

According to an embodiment, the polymer formulation (F) is at room temperature during the process. Alternatively, the formulation can be heated before and/or during printing, especially if the polymer concentration in the formulation is high. In this case, the temperature can be heated up to 130° C., up to 120° C. or up to 110° C. before and/or during printing.

The present invention also relates to the use of the polymer (P1) of the present invention or of the polymer formulation (F) of the present invention, for the manufacture of 3D objects/articles.

All of the embodiments described above with respect to the polymer (P1) and the polymer formulation (F) do apply equally to the use for the manufacture of 3D objects/articles.

The present invention also relates to 3D objects or 3D articles obtainable, at least in part, from the method of manufacture of the present invention, using the polymer (P1) or the polymer formulation (F) herein described.

The 3D objects or articles obtainable by such method of manufacture can be used in a variety of final applications. Mention can be made in particular of implantable device, dental prostheses, brackets and complex shaped parts in the aerospace industry and under-the-hood parts in the automotive industry.

Should the disclosure of any patents, patent applications, and publications which are incorporated herein by reference conflict with the description of the present application to the extent that it may render a term unclear, the present description shall take precedence.

The invention will be now described in more detail with reference to the following examples whose purpose is merely illustrative and not limitative of the scope of the invention.

### EXAMPLES

Two PAE polymers (P1) and corresponding PAE polymers (P2) according to the present invention were prepared and characterized.

Molecular Weight (Mn, Mw, Mz and Mz+1)

The molecular weights were measured by gel permeation chromatography (GPC), using methylene chloride as a mobile phase. Two 5μ mixed D columns with guard column from Agilent Technologies were used for separation. An ultraviolet detector of 254 nm was used to obtain the chromatogram. A flow rate of 1.5 ml/min and injection volume of 20 μL of a 0.2 w/v % solution in mobile phase was selected. Calibration was performed with 12 narrow molecular weight polystyrene standards (Peak molecular weight range: 371,000 to 580 g/mol). The number average molecular weight Mn, weight average molecular weight Mw, higher average molecular weight Mz and Mz+1, were reported.

### Example 1. Synthesis of PPSU Polymer (P1-A) and PPSU Polymer (P2-A)

This example demonstrates the synthesis of a polymer (P1-A), comprising recurring units R_{PPSU}, poly(biphenyl ether sulfone), according to Scheme 1.

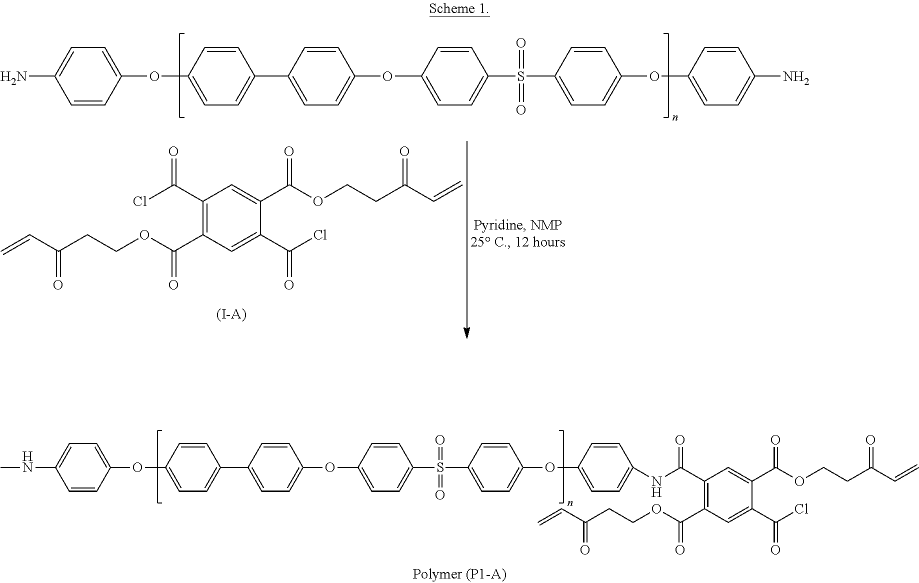

Formation of the Reactants Amine-PPSU and PDMA-HEA (I-A)

The Amine-PPSU was synthetized according to the methods described in (1) B. J. Sundell, K.-s. Lee, A. Nebipasagil, A. Shaver, J. R. Cook, E.-S. Jang, B. D. Freeman, J. E. McGrath, Industrial & Engineering Chemistry Research 2014, 53, 2583-2593. (2) J. Mecham, H. K. Shobha, F. Wang, W. Harrison, J. E. McGrath, Polym. Prepr. (Am. Chem. Soc., Div. Polym. Chem.) 2000, 41, 1388-1389. (3) C. Puglisi, F. Samperi, G. Cicala, A. Recca, C. L. Restuccia, Polymer 2006, 47, 1861-1874. (4) M. W. Muggli, T. C. Ward, C. Tchatchoua, Q. Ji, J. E. McGrath, J. Polym. Sci., Part B: Polym. Phys. 2003, 41, 2850-2860.

The PDMA-HEA diacid chloride (I-A) (PMDA-HEA-CI, Mw: 455.24 g/mol) was synthesized according to methods reported in the literature. Reference can be made in particular to Hedge et al. “3D Printing All-Aromatic Polyimides using Mask-Projection Stereolithography: Processing the Nonprocessable” (Adv. Mater. 2017, 29).

Formation of the PPSU Polymer (P1-A)

A three-neck flask with a gas-inlet and thermocouple was charged with 8.66 g of Amine-PPSU, 0.3 mL of pyridine and 50 mL NMP with overhead stirring. A separate solution of the crude PMDA-HEA-CI (I-A) (0.7556 g, 3.32 mmol) was then dissolved in 40 mL dry NMP and added dropwise over an 1 h while on an ice bath. After complete addition, the mixture was then left stirring at room temperature for 4 h. After mixing, the solution was coagulated into ˜500 mL MeOH and washed 3 times with MeOH with heavy agitation during each wash. Yield 8.4 g.

Formation of the PPSU Polymer (P2-A)

This example also demonstrates the synthesis of a PPSU polymer (P2-A), according to Scheme 2.

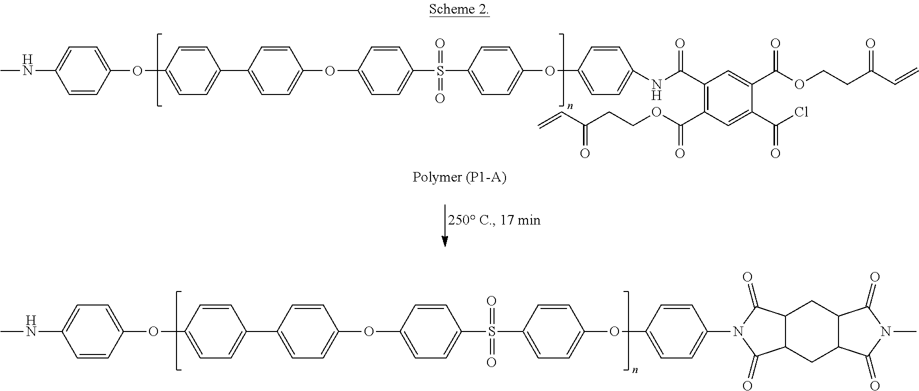

A tube furnace was charged with 600 mg of the PPSU polymer (P1-A) and was purged for 20 min under a flow of N₂. A flow of N₂ kept until the sample was taken out of the furnace. After the purge, the tube was then heated at 250° C. for 17 min. After heating, the tube was allowed to cool to room temperature (˜1.5 h) and the sample was removed from the furnace.

Characterization of the PPSU polymers (P1-A) and (P2-A) The different polymers were characterized by GPC to determine molecular weights (Mn & Mw) and polydispersity index (PDI). The results are summarized in Table 1.

TABLE 1

| | Mw | Mn | Mw/Mn | Mz | Mz + 1 | Mz/Mw |
|---|---|---|---|---|---|---|
| Amine | 23,641 | 7,143 | 3.31 | 39,498 | 51,290 | 1.67 |
| PPSU | | | | | | |
| PPSU | 54,887 | 18,736 | 2.93 | 82,446 | 102,715 | 1.5 |
| (P1-A) | | | | | | |
| PPSU | 80,222 | 28,872 | 2.78 | 97,603 | 107,892 | 1.22 |
| (P2-A) | | | | | | |

### Example 2. Synthesis of PSU Polymer (P1-B) and PSU Polymer (P2-B)

This example demonstrates the synthesis of a polymer (P1-B), comprising recurring units R_{PSU}, polysulfone, according to Scheme 3.

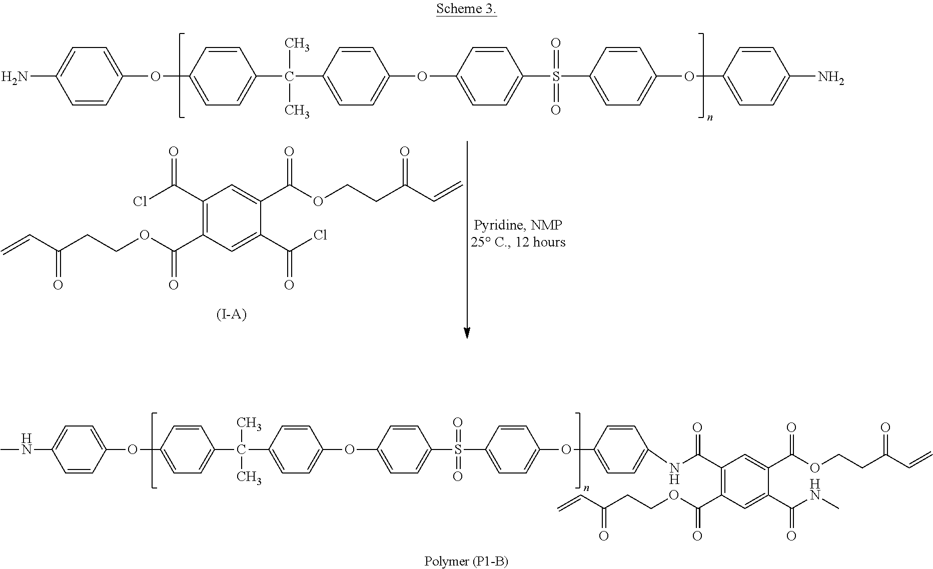

Formation of the Reactants Amine-PSU and PDMA-HEA (I-A)

The Amine-PSU (Ill) was synthetized according to methods described in (1) B. J. Sundell, K.-s. Lee, A. Nebipasagil, A. Shaver, J. R. Cook, E.-S. Jang, B. D. Freeman, J. E. McGrath, Industrial & Engineering Chemistry Research 2014, 53, 2583-2593. (2) J. Mecham, H. K. Shobha, F. Wang, W. Harrison, J. E. McGrath, Polym. Prepr. (Am. Chem. Soc., Div. Polym. Chem.) 2000, 41, 1388-1389. (3) C. Puglisi, F. Samperi, G. Cicala, A. Recca, C. L. Restuccia, Polymer 2006, 47, 1861-1874. (4) M. W. Muggli, T. C. Ward, C. Tchatchoua, Q. Ji, J. E. McGrath, J. Polym. Sci., Part B: Polym. Phys. 2003, 41, 2850-2860.

The PDMA-HEA diacid chloride (I-A) (PMDA-HEA-CI, Mw: 455.24 g/mol) was synthesized according to methods reported in the literature. Reference can be made in particular to Hedge et al. “3D Printing All-Aromatic Polyimides using Mask-Projection Stereolithography: Processing the Nonprocessable” (Adv. Mater. 2017, 29).

Formation of the PSU Polymer (P1-B)

A three-neck flask with a gas-inlet and thermocouple was charged with 7.6322 g of Amine-PSU, 0.2 mL of pyridine and 40 mL dry NMP with overhead stirring. A separate solution of the crude PMDA-HEA-CI (I-A) (0.54 g, 2.37 mmol) was then dissolved in dry 40 mL dry NMP and added dropwise over an 1 h while on an ice bath. After complete addition, the mixture was then left stirring at room temperature for 4 h. After mixing, the solution was coagulated into ˜500 mL MeOH and washed 3 times with MeOH with heavy agitation during each wash. Yield 6.07 g.

Formation of the PSU Polymer (P2-B)

This example demonstrates the synthesis of a PSU polymer (P2-B), according to Scheme 4.

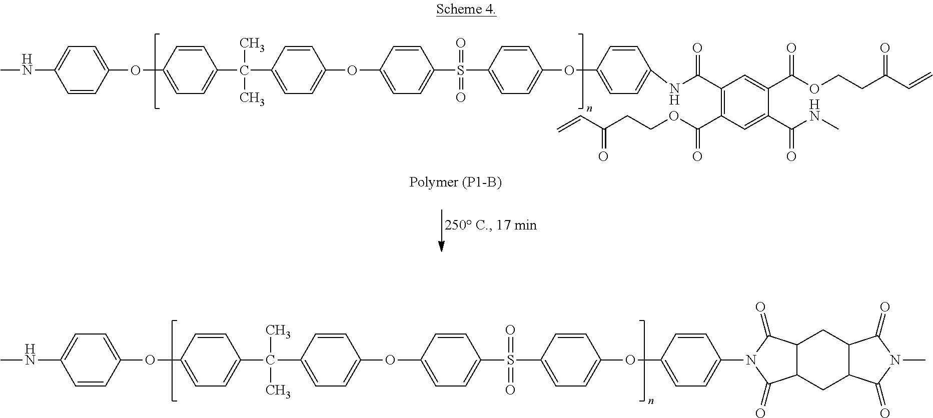

A tube furnace was charged with 600 mg of the PSU polymer (P1) and was purged for 20 min under a flow of N₂. A flow of N₂ kept until the sample was taken out of the furnace. After the purge, the tube was then heated at 250° C. for 17 min. After heating, the tube was allowed to cool to room temperature (˜1.5 h) and the sample was removed from the furnace.

Characterization of the PSU Polymers (P1-B) and (P2-B)

The material obtained by the aforementioned process was characterized by GPC to determine molecular weights (Mn & Mw) and polydispersity index (PDI). The results are summarized in Table 2.

TABLE 2

| | Mw | Mn | Mw/Mn | Mz | Mz + 1 | Mz/Mw |
|---|---|---|---|---|---|---|
| Amine-PSU | 17,272 | 5,564 | 3.1 | 29,809 | 40,118 | 1.73 |
| PSU (P1-B) | 29,323 | 10,275 | 2.85 | 47,693 | 63,283 | 1.63 |
| PSU (P2-B) | 34,896 | 10,737 | 3.25 | 54,273 | 69,431 | 1.56 |

1. A poly(aryl ether) (PAE) polymer (P1) comprising:
recurring units R_{PAES} and/or recurring units R_{PAEK}, wherein
recurring units R_{PAES} are according to formula (M): 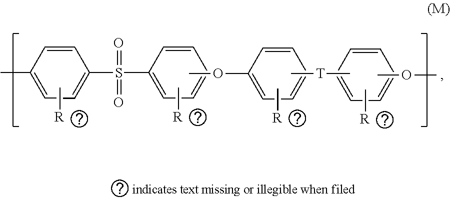
recurring units R_{PAEK} are selected from the group consisting of units of formulas (J-A) to (J-D): 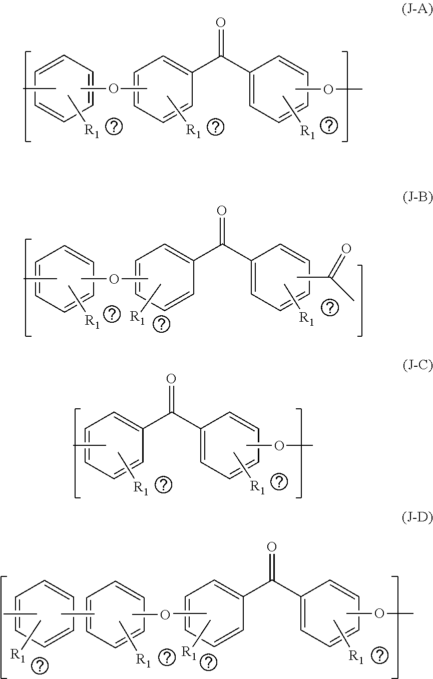
at least one group of formula (L1) to (L4): 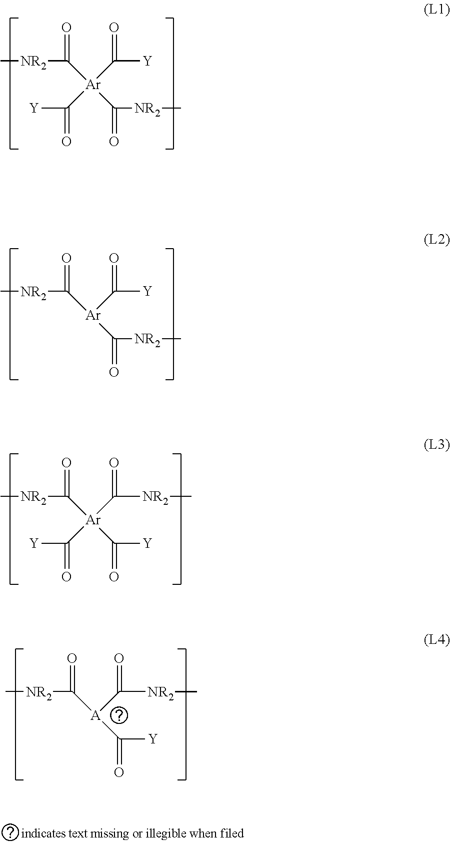
wherein
each R₁ is independently selected from the group consisting of a halogen, alkyl, alkenyl, alkynyl, aryl, ether, thioether, carboxylic acid, ester, amide, imide, alkali or alkaline earth metal sulfonate, alkyl sulfonate, alkali or alkaline earth metal phosphonate, alkyl phosphonate, amine and quaternary ammonium;
each i is independently selected from 0 to 4;
T is selected from the group consisting of a bond, —CH₂—; —O—; —SO₂—; —S—; —C(O)—; —C(CH₃)₂—; —C(CF₃)₂—; —C(═CCl₂)—; —C(CH₃)(CH₂CH₂COOH)—; —N═N—; —RₓC═CR_{y}—, where each Rₓ and R_{y}, independently of one another, is a hydrogen or a C1-C12-alkyl, C1-C12-alkoxy, or C6-C18-aryl group; —(CH₂)ₘ and —(CF₂)ₘ with m being an integer from 1 to 6; an aliphatic divalent group, linear or branched, of up to 6 carbon atoms; and combinations thereof;
Ar is a tetravalent aromatic moiety selected from the group consisting of a substituted or unsubstituted, saturated, unsaturated or aromatic monocyclic and polycyclic group having 5 to 50 carbon atoms;
Ar′ is a trivalent aromatic moiety selected from the group consisting of a substituted or unsubstituted, saturated, unsaturated or aromatic monocyclic and polycyclic group having 5 to 50 carbon atoms;
each R₂ is independently H or an alkyl;
each Y is independently selected from the group consisting of:
O—(CH₂)ₖ—O—CO—CH═CHR₄, with k being from 1 to 20; and R₄ being H or an alkyl;
O—(CH₂)ₚ—Ar—CR₅═CHR₆ or O—(CH₂)ₚ—OAr—CR₅═CHR₆, wherein p is from 0 to 20; Ar comprises one or two aromatic or heteroaromatic rings; R₅ and R₆ are H, an alkyl, a phenyl or a COOR₇ with R₇ being H or an alkyl;
O—(CH₂)_{q}—CH═CHR₈ with q being from 0 to 20; and R₈ being H or an alkyl;
O—(CH₂)ᵣ—O—CH═CHR₉ with r being from 0 to 20; and R₉ being H or an alkyl; 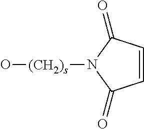
with s being from 0 to 20;
O⁻, NRₐR_{b}R_{c}H⁺—(CH₂)ₖ—O—CO—CH═CHR₄, with k and R₄ as above-defined,
O⁻, NRₐR_{b}R_{c}H⁺—(CH₂)ₚ—Ar—CR₅═CHR₆, with p, Ar, R₅ and R₆ as above-defined,
O⁻, NRₐR_{b}R_{c}H⁺—(CH₂)ₚ—OAr—CR₅═CHR₆ with p, Ar, R₅ and R₆ as above-defined,
O⁻, NRₐR_{b}R_{c}H⁺—(CH₂)_{q}—CH═CHR₈, with q and R₈ as above-defined,
O⁻, NRₐR_{b}R_{c}H⁺—(CH₂)ᵣ—O—CH═CHR₉, with r and R₉ as above-defined, 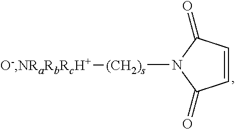
with s as above-defined,
wherein Rₐ, R_{b}, and R_{c} are independently H or an alkyl.

2. The PAE polymer (P1) of claim 1, wherein the recurring units R_{PAES} and/or recurring units R_{PAEK} are in blocks comprising at least two recurring units.

3. The PAE polymer (P1) of claim 1, comprising at least 50 mol. % (based on the total number of moles in the polymer) of recurring units of formula (M) in which T is selected from the group consisting of a bond, —SO₂— and —C(CH₃)₂—.

4. The PAE polymer (P1) of claim 1, wherein Y is O—(CH₂)ₖ—O—CO—CH═CHR₄, with k being from 2 to 6 and R₄ being H or CH₃.

5. The PAE polymer (P1) of claim 1, wherein the PAE polymer (P1) has a number average molecular weight (Mn) (as measured by gel permeation chromatography (GPC) using N,N dimethyl formamide (DMF) as a mobile phase, with polystyrene standards) of:
less than 100,000 g/mol; and/or
more than 1,000 g/mol.

6. A formulation (F), comprising:
the PAE polymer (P1) of claim 1; and
one solvent;
optionally one photoinitiator;
optionally one blocker.

7. The formulation (F) of claim 6, wherein:
the solvent is selected from the group consisting of chlorobenzene, chloroform, N-methylpyrrolidone (NMP), N,N-dimethylformamide (DMF), N,N-dimethylacetamide (DMAC), 1,3-dimethyl-2-imidazolidinone, tetrahydrofuran (THF), dimethyl sulfoxide (DMSO) and sulfolane;
the photoinitiator is selected from the group consisting of 2,2-dimethoxy-2-phenylacetophenone (DMPA), diphenyl(2,4,6-trimethylbenzoyl)phosphine oxide and phenylbis(2,4,6-trimethylbenzoyl)phosphine oxide; and/or
the blocker is selected from the group consisting of avobenzone and 2,5-Bis(5-tert-butyl-benzoxazol-2-yl)thiophene.

8. A process for preparing the PAE polymer (P1) of claim 1, comprising:
a) providing a PAE polymer (P0) of formula RₙRₘN—P—NRₙRₘ, wherein P comprises recurring units R_{PAES} and/or recurring units R_{PAE}K, wherein
recurring units R_{PAES} are according to formula (M): 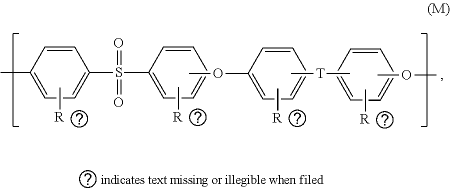
recurring units R_{PAEK} are selected from the group consisting of units of formulas (J-A) to (J-D): 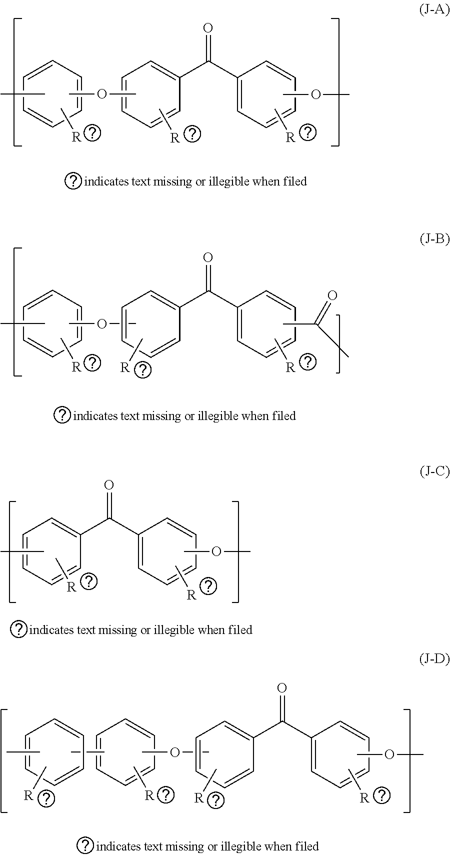
wherein
each R₁ is independently selected from the group consisting of a halogen, alkyl, alkenyl, alkynyl, aryl, ether, thioether, carboxylic acid, ester, amide, imide, alkali or alkaline earth metal sulfonate, alkyl sulfonate, alkali or alkaline earth metal phosphonate, alkyl phosphonate, amine and quaternary ammonium;
each Rₙ and Rₘ is independently H or an alkyl;
each i is independently selected from 0 to 4;
T is selected from the group consisting of a bond, —CH₂—; —O—; —SO₂—; —S—; —C(O)—; —C(CH₃)₂—; —C(CF₃)₂—; —C(═CCl₂)—; —C(CH₃)(CH₂CH₂COOH)—; —N═N—; —RₓC═CR_{y}—, where each Rₓ and R_{y}, independently of one another, is a hydrogen or a C1-C12-alkyl, C1-C12-alkoxy, or C6-C18-aryl group; —(CH₂)ₘ and —(CF₂)ₘ with m being an integer from 1 to 6; an aliphatic divalent group, linear or branched, of up to 6 carbon atoms; and combinations thereof.
b) reacting the PAE polymer (P0) with a compound of formula (I), (II), (III) or (IV): 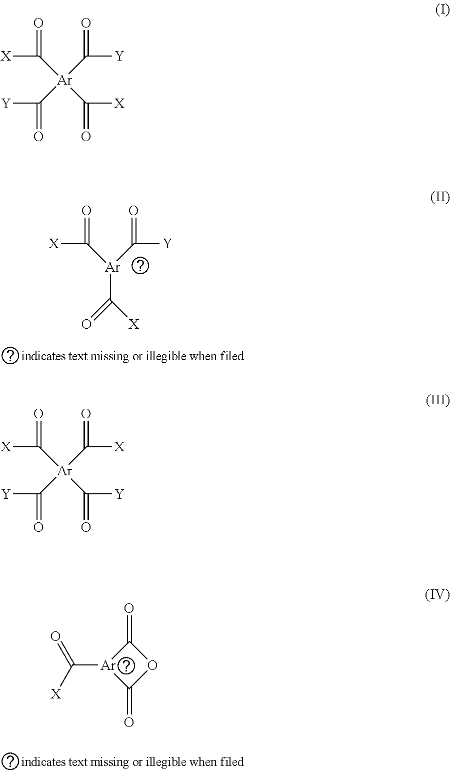
wherein:
Ar is a tetravalent aromatic moiety, selected from the group consisting of a substituted or unsubstituted, saturated, unsaturated or aromatic monocyclic and polycyclic group having 5 to 50 carbon atoms;
Ar′ is a trivalent aromatic moiety selected from the group consisting of a substituted or unsubstituted, saturated, unsaturated or aromatic monocyclic and polycyclic group having 5 to 50 carbon atoms;
X is Cl, Br, F or I;
each Y is independently selected from the group consisting of:
O—(CH₂)ₖ—O—CO—CH═CHR₄, with k being from 1 to 20; and R₄ being H or an alkyl,
O—(CH₂)ₚ—Ar—CR₅═CHR₆ or O—(CH₂)ₚ—OAr—CR₅═CHR₆, wherein p is from 0 to 20; Ar comprises one or two aromatic or heteroaromatic rings; R₅ and R₆ are H, an alkyl, a phenyl or a COOR₇ with R₇ being H or an alkyl,
O—(CH₂)_{q}—CH═CHR₈ with q being from 0 to 20; and R₈ being H or an alkyl;
O—(CH₂)ᵣ—O—CH═CHR₉ with r being from 0 to 20; and R₉ being H or an alkyl; 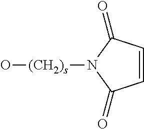
with s being from 0 to 20;
O⁻, NRₐR_{b}R_{c}H⁺—(CH₂)ₖ—O—CO—CH═CHR₄, with k and R₄ as above-defined;
O⁻, NRₐR_{b}R_{c}H⁺—(CH₂)ₚ—Ar—CRs═CHR₆, with p, Ar, R₅ and R₆ as above-defined;
O⁻, NRₐR_{b}R_{c}H⁺—(CH₂)ₚ—OAr—CRs═CHR₆ with p, Ar, R₅ and R₆ as above-defined;
O⁻, NRₐR_{b}R_{c}H⁺—(CH₂)_{q}—CH═CHR₈, with q and R₈ as above-defined;
O⁻, NRₐR_{b}R_{c}H⁺—(CH₂)ᵣ—O—CH═CHR₉, with r and R₉ as above-defined; 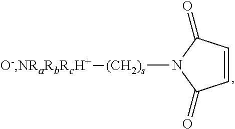
with s as above-defined;
wherein Rₐ, R_{b}, and R_{c} are independently H or an alkyl,
in the presence of a polar aprotic solvent and an organic base.

9. The process of claim 8, wherein
the solvent is selected from the group consisting of chlorobenzene, chloroform, N-methylpyrrolidone (NMP), N,Ndimethylformamide (DMF), N,N-dimethylacetamide (DMAC), 1,3-dimethyl-2-imidazolidinone, tetrahydrofuran (THF), dimethyl sulfoxide (DMSO) and sulfolane, and
the organic base is selected from the group consisting of pyridine and alkylamine.

10. A process for preparing the PAE polymer (P1) of claim 1, comprising:
a) providing a PAE polymer (P0) of formula RₙRₘN—P—NRₙRₘ, wherein P comprises recurring units R_{PAES} and/or recurring units R_{PAEK}, wherein
recurring units R_{PAES} are according to formula (M): 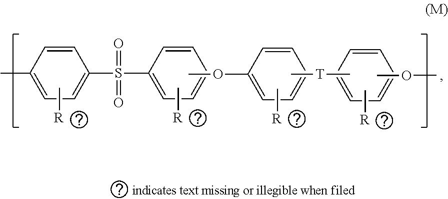
recurring units R_{PAEK} are selected from the group consisting of units of formulas (J-A) to (J-D): 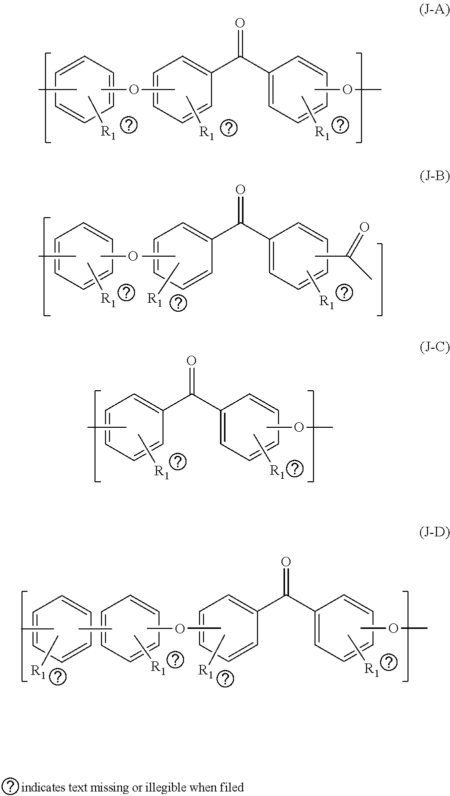
wherein
each R₁ is independently selected from the group consisting of a halogen, alkyl, alkenyl, alkynyl, aryl, ether, thioether, carboxylic acid, ester, amide, imide, alkali or alkaline earth metal sulfonate, alkyl sulfonate, alkali or alkaline earth metal phosphonate, alkyl phosphonate, amine and quaternary ammonium;
each Rₙ and Rₘ is independently H or an alkyl;
each i is independently selected from 0 to 4;
T is selected from the group consisting of a bond, —CH₂—; —O—; —SO₂—; —S—; —C(O)—; —C(CH₃)₂—; —C(CF₃)₂—; —C(═CCl₂)—; —C(CH₃)(CH₂CH₂COOH)—; —N═N—; —RₓC═CR_{y}—, where each Rₓ and R_{y}, independently of one another, is a hydrogen or a C1-C12-alkyl, C1-C12-alkoxy, or C6-C18-aryl group; —(CH₂)ₘ and —(CF₂)ₘ with m being an integer from 1 to 6; an aliphatic divalent group, linear or branched, of up to 6 carbon atoms; and combinations thereof.
b) reacting the PAE polymer (P0) with a compound of formula (V), (V), (VI) or (VIII): 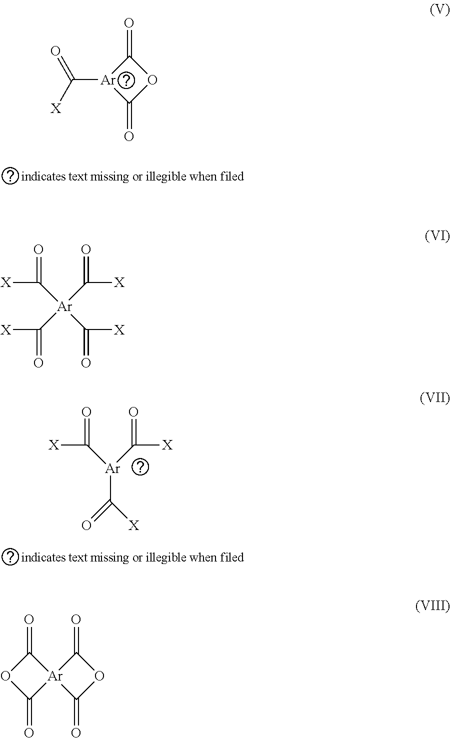
wherein:
Ar is a tetravalent aromatic moiety, selected from the group consisting of a substituted or unsubstituted, saturated, unsaturated or aromatic monocyclic and polycyclic group having 5 to 50 carbon atoms;
Ar′ is a trivalent aromatic moiety selected from the group consisting of a substituted or unsubstituted, saturated, unsaturated or aromatic monocyclic and polycyclic group having 5 to 50 carbon atoms;
X is OH, Cl, Br, F or I;
c) reacting the polymer obtained in step b) with a compound selected from the group consisting of:
NRₐR_{b}R_{c}—(CH₂)ₖ—O—CO—CH═CHR₄, with k and R₄ as above-defined,
NRₐR_{b}R_{c}—(CH₂)ₚ—Ar—CR₅═CHR₆, with p, Ar, R₅ and R₆ as above-defined,
NRₐR_{b}R_{c}—(CH₂)ₚ—OAr—CR₅═CHR₆ with p, Ar, R₅ and R₆ as above-defined,
NRₐR_{b}R_{c}—(CH₂)_{q}—CH═CHR₈, with q and R₈ as above-defined,
NRₐR_{b}R_{c}—(CH₂)ᵣ—O—CH═CHR₉, with r and R₉ as above-defined, 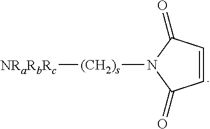
with s as above-defined,
wherein Rₐ, R_{b}, and R_{c} are independently H or an alkyl.

11. A method for manufacturing a three-dimensional (3D) article with an additive manufacturing system, comprising:
providing a formulation (F) according to claim 6,
printing layers of the three-dimensional (3D) article from the formulation (F).

12. The method of claim 11, wherein the step of printing comprises irradiating the polymer composition with light, light.

13. A three-dimensional Three dimensional (3D) article or object manufactured, at least in part, by the method of claim 11.

14. The 3D article or object of claim 13, comprising:
recurring units R_{PAES} and/or recurring units R_{PAEK}, wherein
recurring units R_{PAES} are according to formula (M): 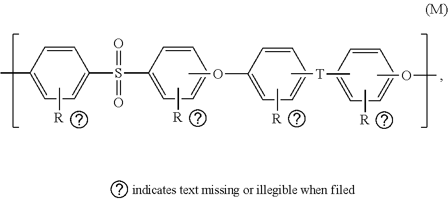
recurring units R_{PAEK} are selected from the group consisting of units of formulas (J-A) to (J-D): 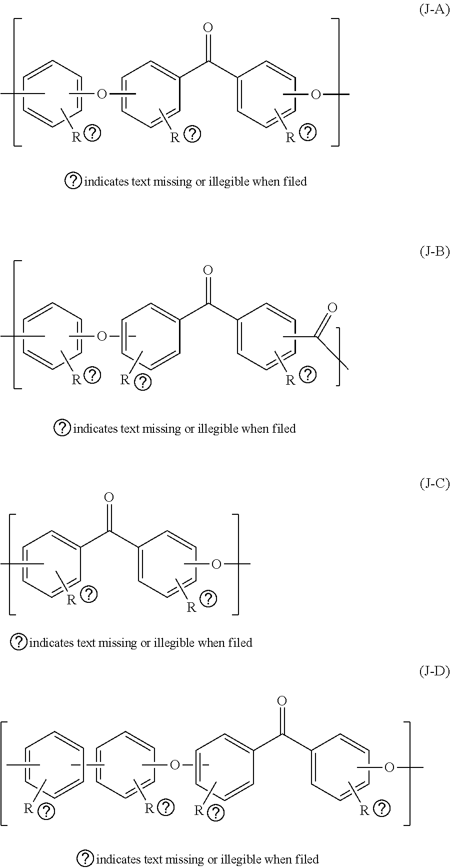
at least one group of formula (K): 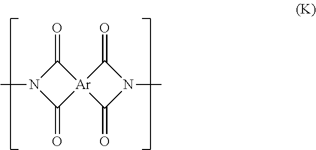
wherein:
each R₁ is independently selected from the group consisting of a halogen, alkyl, alkenyl, alkynyl, aryl, ether, thioether, carboxylic acid, ester, amide, imide, alkali or alkaline earth metal sulfonate, alkyl sulfonate, alkali or alkaline earth metal phosphonate, alkyl phosphonate, amine and quaternary ammonium;
each i is independently selected from 0 to 4;
T is selected from the group consisting of a bond, —CH₂—; —O—; —SO₂—; —S—; —C(O)—; —C(CH₃)₂—; —C(CF₃)₂—; —C(═CCl₂)—; —C(CH₃)(CH₂CH₂COOH)—; —N═N—; —RₐC═CR_{b}—, where each Rₐ and R_{b}, independently of one another, is a hydrogen or a C1-C12-alkyl, C1-C12-alkoxy, or C6-C18-aryl group; —(CH₂)ₘ and —(CF₂)ₘ with m being an integer from 1 to 6; an aliphatic divalent group, linear or branched, of up to 6 carbon atoms; and combinations thereof; and
Ar is a tetravalent aromatic moiety, selected from the group consisting of a substituted or unsubstituted, saturated, unsaturated or aromatic monocyclic and polycyclic group having 5 to 50 carbon atoms.

15. A method for the manufacture of 3D objects, the method comprising printing the 3D objects, with the polymer (P1) according to claim 1, by stereolithography technology (SLA), ink-jet process, direct ink writing (DIW) or digital light processing (DLP), where the polymer (P1) is printed alone or in a formulation with one solvent, optionally one photoinitiator, and optionally one blocker.
